(19) United States
(12) Patent Application Publication
(10) Pub. No.: US 2016/0172284 A1
(43) Pub. Date: Jun. 16, 2016

(54) Integrated Power Assembly with Stacked Individually Packaged Power Devices

(71) Applicant: Infineon Technologies Americas Corp., EI Segundo, CA (US)

(72) Inventor: Eung San Cho, Torrance, CA (US)

(73) Assignee: INFINEON TECHNOLOGIES AMERICAS CORP.

(21) Appl. No.: 14/938,749

(22) Filed: Nov. 11, 2015

Related U.S. Application Data
(60) Provisional application No. 62/090,501, filed on Dec. 11, 2014.

(51) Int. Cl. H01L 23/495

(52) U.S. Cl. CPC H01L 23/49575; H01L 23/49537

(57) ABSTRACT

An integrated power assembly is disclosed. The integrated power assembly includes a first leadframe having partially etched segments, a first semiconductor die configured for attachment to a partially etched segment of the first leadframe, a second leadframe having a legless conductive clip coupled to a top surface of the first semiconductor die. The integrated power assembly also includes a third leadframe over the second leadframe and having a partially etched segment, a second semiconductor die configured for attachment to the partially etched segment of the third leadframe, wherein the second semiconductor die is coupled to the first semiconductor die through the partially etched segment of the third leadframe, and wherein the partially etched segment of the third leadframe is situated on the legless conductive clip of the second leadframe.

The present application claims the benefit of and priority to a provisional patent application entitled “Package on Package with Dual Gauge,” Ser. No. 62/090,501 filed on Dec. 11, 2014. The disclosure in this provisional application is hereby incorporated fully by reference into the present application.

### BACKGROUND

To improve form factor, electrical and thermal performance, and manufacturing cost of power converters, it is often desirable to integrate components of a power converter circuit into a power semiconductor package. Today's power conversion system design demands for versatility and adaptability in packaging different types power transistors in a variety of configurations, such as a half-bridge or a cascoded switch.

In a conventional power semiconductor package, individual semiconductor dies are arranged side by side and coupled to a shared support surface, such as a printed circuit board (PCB), through their respective conductive clips. However, the routing between semiconductor dies through the conductive clips and the PCB can undesirably increase electrical resistance. Also, the form factor of the laterally arranged individually semiconductor dies requires significant area to be reserved on the PCB. Moreover, power devices often generate significant heat during operation, which can cause their temperature to rise outside of the suitable temperature range if the heat is not sufficiently dissipated from the power devices.

Thus, there is a need in the art to provide an integrated power assembly having individually packaged power devices for increasing power device selection and variety in packaging the power devices, while maintaining or improving thermal and electrical performance and form factor.

### SUMMARY

The present disclosure is directed to an integrated power assembly with stacked individually packaged power devices, substantially as shown in and/or described in connection with at least one of the figures, and as set forth in the claims.

### BRIEF DESCRIPTION OF THE DRAWINGS

FIG. 1A illustrates an exemplary circuit diagram of a power converter, according to one implementation of the present application.

FIG. 1B illustrates an exemplary circuit diagram of a composite switch, according to one implementation of the present application.

FIG. 2A illustrates a cross-sectional view of a portion of an exemplary integrated power assembly of a power switching stage, according to one implementation of the present application.

FIG. 2B illustrates a cross-sectional view of a portion of an exemplary integrated power assembly of a power switching stage, according to one implementation of the present application.

FIG. 2C illustrates a cross-sectional view of an exemplary integrated power assembly of a power switching stage, according to one implementation of the present application.

FIG. 3 illustrates a perspective view of a three-phase inverter, according to one implementation of the present application.

FIG. 4A illustrates a cross-sectional view of a portion of an exemplary integrated power assembly of a composite switch, according to one implementation of the present application.

FIG. 4B illustrates a cross-sectional view of a portion of an exemplary integrated power assembly of a composite switch, according to one implementation of the present application.

FIG. 4C illustrates a cross-sectional view of an exemplary integrated power assembly of a composite switch, according to one implementation of the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

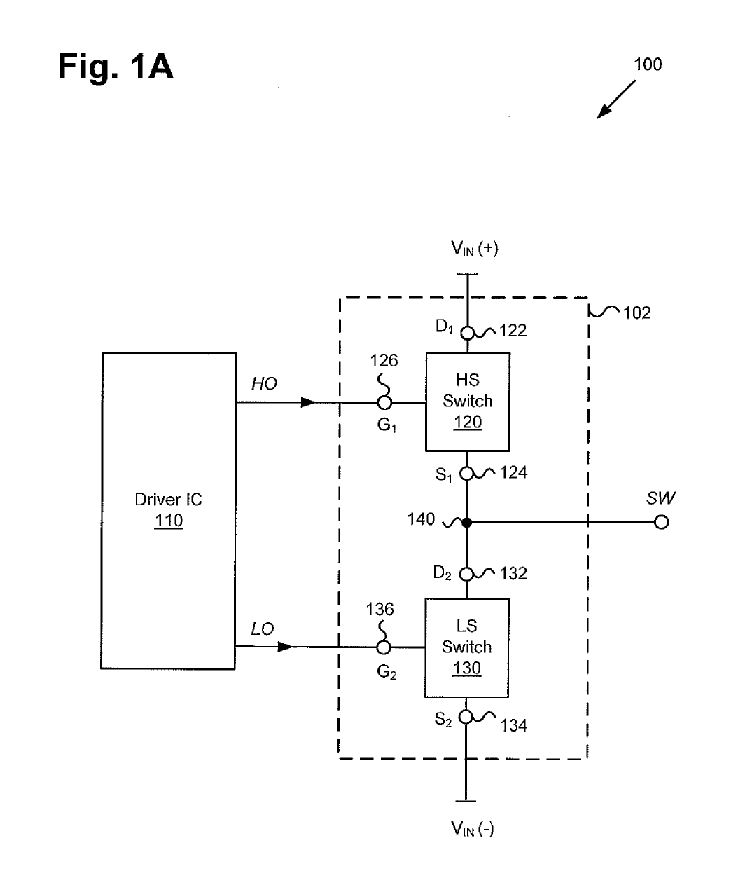

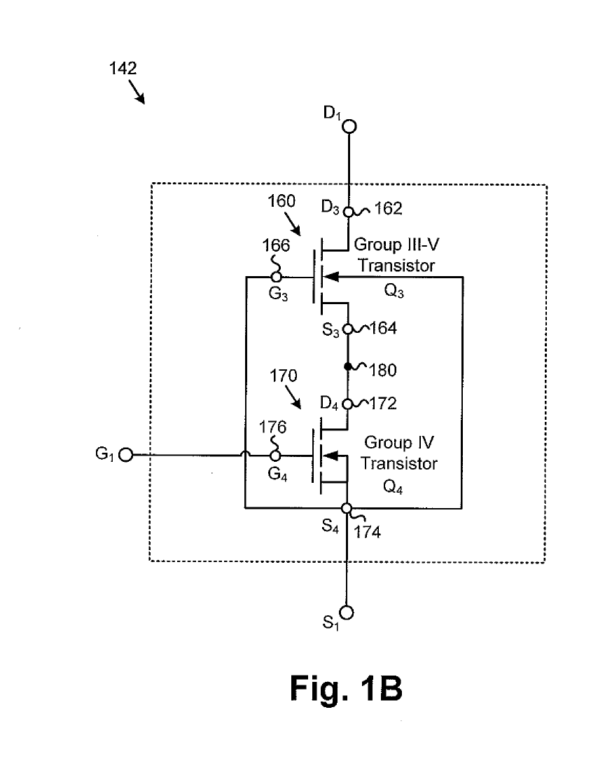

Referring now to FIG. 1A, FIG. 1A illustrates a circuit schematic of an exemplary power conversion circuit, in accordance with an implementation of the present application. As shown in FIG. 1A, power conversion circuit 100 includes driver integrated circuit (IC) 110 and power switching stage 102 having high-side switch 120 and low-side switch 130. Driver IC 110 is configured to provide high-side drive signal HO and low-side drive signal LO, which are gate drive signals, to drive respective high-side switch 120 and low-side switch 130 of power switching stage 102. In power switching stage 102, high-side switch 120 and low-side switch 130 are coupled between positive input terminal V_{IN(+)} and negative input terminal V_{IN(-)}, and switched node 140 as an output node is between high-side switch 120 and low-side switch 130.

As illustrated in FIG. 1A, high-side switch 120 (e.g., Q₁) includes a control transistor having drain 122 (e.g., D₁), source 124 (e.g., S₁) and gate 126 (e.g., G₁). Low-side switch 130 (e.g., Q₂) includes a synchronous (hereinafter “sync”) transistor having drain 132 (e.g., D₂), source 134 (e.g., S₂) and gate 136 (e.g., G₂). Drain 122 of high-side switch 120 is coupled to positive input terminal V_{IN(+)}, while source 124 of high-side switch 120 is coupled to switched node 140. Gate 126 of high-side switch 120 is coupled to driver IC 110, which provides high-side drive signal HO to gate 126. As illustrated in FIG. 1A, drain 132 of low-side switch 130 is coupled to switched node 140, while source 134 of low-side switch 130 is coupled to negative input terminal V_{IN(-)}. Gate 136 of low-side switch 130 is coupled to driver IC 110, which provides low-side drive signal LO to gate 136.

In an implementation, at least one of high-side switch 120 and low-side switch 130 includes a group IV semiconductor device, such as a silicon metal-oxide-semiconductor field effect transistor (MOSFET). In another implementation, at least one of high-side switch 120 and low-side switch 130 includes a group III-V semiconductor device, such as a gallium nitride (GaN) high electron mobility transistor (HEMT). In other implementations, high-side switch 120 and low-side switch 130 may include other suitable semiconductor devices, such as bipolar junction transistors (BJT's) and insulated gate bipolar transistors (IGBTs).

In an implementation, high-side switch 120 and low-side switch 130 (also referred to as power switch 120 and power switch 130, respectively) may each include a group 111-V semiconductor device (e.g., a III-Nitride transistor) and a group IV semiconductor device (e.g., a silicon transistor). By including at least one III-Nitride transistor in power switching stage 102, power conversion circuit 100 may exploit the high breakdown fields, high saturation velocities, and two-dimensional electron gases (2DEGs) offered by III-Nitride materials. For example, it may be desirable for the at least one III-Nitride transistor to operate as an enhancement mode device in power conversion circuit 100. This may be accomplished by coupling the at least one III-Nitride transistor, such as a depletion mode GaN transistor, in cascode with a group IV transistor to produce an enhancement mode composite switch, such as enhancement mode composite switch 142 in FIG. 1B.

Referring now to FIG. 1B, FIG. 1B illustrates an exemplary circuit diagram of a composite switch having a group III-V transistor in cascode with a group IV transistor, in accordance with an implementation of the present application. Enhancement mode composite switch 142 includes composite source S₁, composite gate G₁ and composite drain D₁. Enhancement mode composite switch 142 may correspond to at least one of high-side switch 120 and low-side switch 130 in FIG. 1A. For example, while one enhancement mode composite switch 142 may be utilized as high-side switch 120, another enhancement mode composite switch 142 may be utilized as low-side switch 130 in power conversion circuit 100 in FIG. 1A. Thus, composite source S₁, composite gate G₁ and composite drain D₁ of enhancement mode composite switch 142 may correspond to source 124 (e.g., S₁), gate 126 (e.g., G₁) and drain 122 (e.g., D₁), respectively, of high-side switch 120. Composite source S₁, composite gate G₁ and composite drain D₁ of enhancement mode composite switch 142 may also correspond to source 134 (e.g., S₂), gate 136 (e.g., G₂) and drain 132 (e.g., D₂), respectively, of low-side switch 130.

As illustrated in FIG. 1B, enhancement mode composite switch 142 includes group III-V transistor 160 in cascode with group IV transistor 170. For example, group III-V transistor 160 may be a III-Nitride heterojunction field-effect transistor (HFET), such as a GaN HEMI. In the present implementation, group III-V transistor 160 is a depletion mode transistor, such as a depletion mode GaN transistor. Group IV transistor 170 may be a silicon based power semiconductor device, such as a silicon power MOSFET. In the present implementation, group IV transistor 170 is an enhancement mode transistor, such as an enhancement mode silicon transistor.

As illustrated in FIG. 1B, group III-V transistor 160 (e.g., Q₃) includes drain 162 (e.g., D₃), source 164 (e.g., S₃) and gate 166 (e.g., Q₃). Group IV transistor 170 (e.g., Q₄) includes drain 172 (e.g., D₄), source 174 (e.g., S₄) and gate 176 (e.g., G₄). Drain 162 of group III-V transistor 160 is coupled to composite drain D₁, while source 164 of group III-V transistor 160 is coupled to switched node 180. Gate 166 of group III-V transistor 160 is coupled to source 174 of group IV transistor 170. As illustrated in FIG. 1B, drain 172 of group IV transistor 170 is coupled to switched node 180, while source 174 of group IV transistor 170 is coupled to composite source S₁. Gate 176 of group IV transistor 170 is coupled to composite gate G₁.

In enhancement mode composite switch 142, drain 172 of group IV transistor 170 is connected to source 164 of group III-V transistor, such that both devices will be in blocking mode under a reverse voltage condition. As configured, group IV transistor 170 may be a low voltage device while group 111-V transistor 160 may be a high voltage device. In enhancement mode composite switch 142, gate 166 of group III-V transistor 160 is connected to source 174 of group IV transistor 170. Thus, group Ill-V transistor 160 may be off absent a bias voltage on gate 176 of group IV transistor 170, such that enhancement mode composite switch 142 is a normally OFF device.

According to an implementation of the present application, group III-V transistor 160 and group IV transistor 170 may be coupled together on a printed circuit board (PCB) in an integrated power assembly. According to an implementation of the present application, group IV transistor 170 is on a group IV semiconductor die situated on a PCB, and group III-V transistor 160 is on a group III-V semiconductor die situated over the group IV semiconductor die. Group III-V transistor 160 may be coupled to group IV transistor 170 in an integrated power assembly, which can provide reduced form factor and enhanced thermal dissipation.

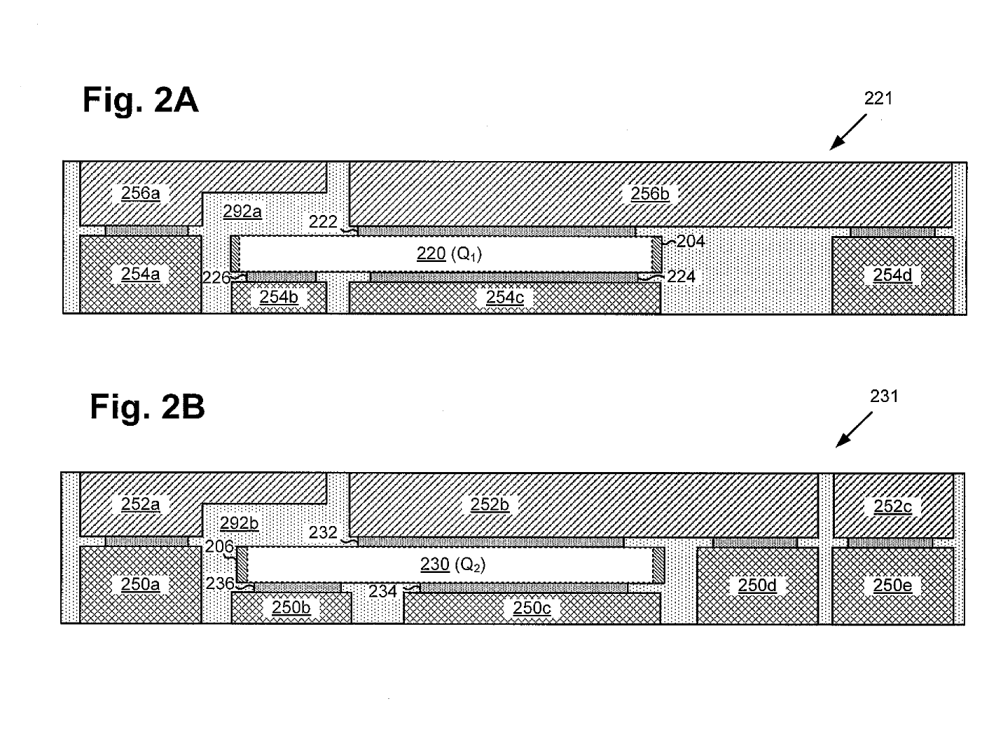

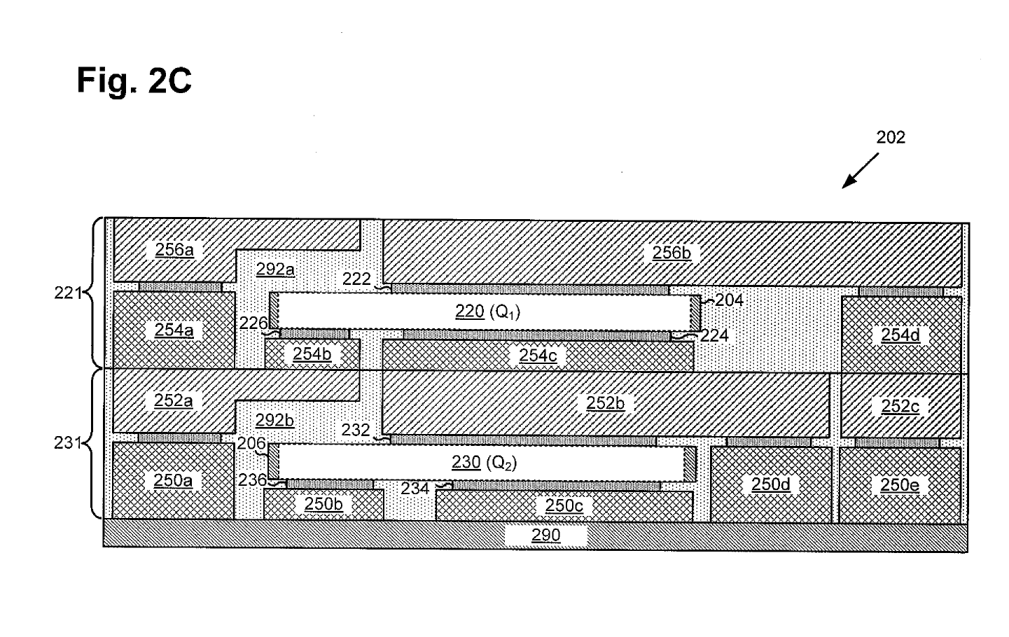

Referring now to FIG. 2A, FIG. 2A illustrates a cross-sectional view of a portion of an exemplary integrated power assembly of a power switching stage, according to one implementation of the present application. As illustrated in FIG. 2A, semiconductor package 221 includes semiconductor die 204 having power switch 220, leadframe 254 having non-etched segments 254a and 254d, and partially etched segments 254b and 254c, and leadframe 256 having partially etched conductive clip 256a and legless conductive clip 256b. Also, semiconductor package 221 includes molding compound 292a substantially covering leadframe 254, semiconductor die 204 and leadframe 256.

As illustrated in FIG. 2A, semiconductor die 204 includes power switch 220. In an implementation, power switch 220 may correspond to high-side switch 120 in power conversion circuit 100 of FIG. 1A. Power switch 220 includes a control transistor having power electrode 222 (e.g., drain electrode) situated on a top surface of semiconductor die 204, and power electrode 224 (e.g., source electrode) and control electrode 226 (e.g., gate electrode) situated on a bottom surface of semiconductor die 204. Power electrodes 222 and 224 and control electrode 226 of power switch 220 may each include a solderable front metal, such as titanium, copper, nickel or silver. Power electrode 222 (e.g., drain electrode) is electrically and mechanically coupled to legless conductive clip 256b of leadframe 256, which is in turn electrically and mechanically coupled to non-etched segment 254d of leadframe 254. Control electrode 226 (e.g., gate electrode) and power electrode 224 (e.g., source electrode) of power switch 220 are electrically and mechanically coupled to partially etched segments 254b and 254c, respectively, of leadframe 254.

As illustrated in FIG. 2A, molding compound 292a substantially covers semiconductor die 204 having power switch 220, leadframe 254 having non-etched segments 254a and 254d, and partially etched segments 254b and 254c, and leadframe 256 having partially etched conductive clip 256a and legless conductive clip 256b. As illustrated in FIG. 2A, the top surfaces of partially etched conductive clip 256a and legless conductive clip 256b, and the bottom surfaces of non-etched segments 254a and 254d, and partially etched segments 254b and 254c of semiconductor package 221 are not covered by molding compound 292a. Thus, semiconductor package 221 can be attached to other semiconductor packages having semiconductor components above and below to form power conversion circuits or cascoded switches, for example.

As illustrated in FIG. 2A, leadframe 256 includes partially etched conductive clip 256a and legless conductive clip 256b. Partially etched conductive clip 256a and legless conductive clip 256b have a substantially coplanar top surface. As illustrated in FIG. 2A, partially etched conductive clip 256a has a non-etched portion and a partially etched portion, where the non-etched portion retains a full thickness of leadframe 256 and the partially etched portion has a thickness that is a fraction of the full thickness of leadframe 256. Partially etched conductive clip 256a is configured to provide clearance for semiconductor die 204, such that power switch 220 on semiconductor die 204 is not electrically shorted to any component to be attached to semiconductor package 221, for example. Legless conductive clip 256b is electrically and mechanically coupled to power electrode 222 of power switch 220. Legless conductive clip 256b is physically separated from partially etched conductive clip 256a, and has a substantially flat body having a substantially uniform thickness, which is the full thickness of leadframe 256.

In the present implementation, partially etched conductive clip 256a and legless conductive clip 256b are made of the same material, and have a substantially uniform composition. In another implementation, partially etched conductive clip 256a and legless conductive clip 256b can be made of different materials, and have different compositions. In the present implementation, partially etched conductive clip 256a and legless conductive clip 256b of leadframe 256 include copper. In another implementation, partially etched conductive clip 256a and legless conductive clip 256b may include other suitable conductive materials, such as aluminum or tungsten.

As illustrated in FIG. 2A, leadframe 254 includes non-etched segments 254a and 254d, and partially etched segments 254b and 254c. Non-etched segments 254a and 254d, and partially etched segments 254b and 254c are different portions of leadframe 254, where non-etched segments 254a and 254d retain a full thickness of leadframe 254, and partially etched segments 254b and 254c are etched, thus having a fraction of the full thickness of leadframe 254 (e.g., a half or a quarter of the thickness of non-etched segment 254a). Non-etched segments 254a and 254d, and partially etched segments 254b and 254c are physically separated from one another. In the present implementation, non-etched segments 254a and 254d, and partially etched segments 254b and 254c are made of the same material, and have a substantially uniform composition. In another implementation, non-etched segments 254a and 254d, and partially etched segments 254b and 254c can be made of different materials, and have different compositions. In the present implementation, non-etched segments 254a and 254d, and partially etched segments 254b and 254c of leadframe 254 may include a metal, such as copper, aluminum, or tungsten, a metal alloy, a tri-metal or other conductive material. In the present implementation, partially etched segments 254b and 254c have a substantially uniform thickness that is a fraction of the full thickness of leadframe 254. In another implementation, partially etched segments 254b and 254c can have different thicknesses.

As illustrated in FIG. 2A, since semiconductor die 204 is situated on partially etched segments, as opposed to non-etched segments, of leadframe 254, the overall height of semiconductor die 204 in semiconductor package 221 can be reduced, such that the leg portion employed in conventional conductive clips can be eliminated. In the present implementation, legless conductive clip 256b has a substantially flat body without a leg portion. In contrast to conventional power semiconductor packages having semiconductor dies attached to non-etched lead segments and conductive clips with leg portions, implementations of the present application utilize partially etched segments 254b and 254c of leadframe 254 to enable semiconductor die 204 to be positioned in semiconductor package 221 with a reduced overall height, which in turn reduces the form factor of semiconductor package 221. In one implementation, semiconductor die 204 may have a thickness of 70 μm (i.e., 70*10⁻⁶ meters) or less, and semiconductor package 221 may have an overall height of 0.4 mm (i.e., 0.4*10⁻³ meters) or less.

In addition, by employing legless conductive clip 256b and semiconductor die 204 configured for attachment to partially etched segments 254b and 254c, the thickness of legless conductive clip 256b can be adjusted to improve high current and voltage handling capability to suit the needs of a particular implementation without significantly affecting the overall height of semiconductor package 221. In addition, because leadframe 256 is exposed on its top surface, and leadframe 254 is exposed on its bottom surface, semiconductor package 221 is highly adaptable, such that it can be directly attached to other semiconductor packages on its top and/or bottom surfaces to form versatile configurations.

Referring now to FIG. 2B, FIG. 2B illustrates a cross-sectional view of a portion of an exemplary integrated power assembly of a power switching stage, according to one implementation of the present application. As illustrated in FIG. 2B, semiconductor package 231 includes semiconductor die 206 having power switch 230, leadframe 250 having non-etched segments 250a, 250d and 250e, and partially etched segments 250b and 250c, and leadframe 252 having partially etched conductive clip 252a, legless conductive clip 252b and non-etched segment 252c. Also, semiconductor package 231 includes molding compound 292b substantially covering leadframe 250, semiconductor die 206 and leadframe 252.

As illustrated in FIG. 2B, semiconductor die 206 includes power switch 230. In an implementation, power switch 230 may correspond to low-side switch 130 in power conversion circuit 100 of FIG. 1A. Power switch 230 includes a synchronous transistor having power electrode 232 (e.g., drain electrode) situated on a top surface of semiconductor die 206, and power electrode 234 (e.g., source electrode) and control electrode 236 (e.g., gate electrode) situated on a bottom surface of semiconductor die 206. Power electrodes 232 and 234 and control electrode 236 of power switch 230 may each include a solderable front metal, such as titanium, copper, nickel or silver. Power electrode 232 (e.g., drain electrode) is electrically and mechanically coupled to legless conductive clip 252b of leadframe 252, which is in turn electrically and mechanically coupled to non-etched segment 250d of leadframe 250. Control electrode 236 (e.g., gate electrode) and power electrode 234 (e.g., source electrode) of power switch 230 are electrically and mechanically coupled to partially etched segments 250b and 250c, respectively, of leadframe 250.

As illustrated in FIG. 2B, molding compound 292b substantially covers semiconductor die 206 having power switch 230, leadframe 250 having non-etched segments 250a, 250d and 250e, and partially etched segments 250b and 250c, and leadframe 252 having partially etched conductive clip 252a, legless conductive clip 252b and non-etched segment 252c. As illustrated in FIG. 2B, the top surfaces of partially etched conductive clip 252a, legless conductive clip 252b and non-etched segment 252c, and the bottom surfaces of non-etched segments 250a, 250d and 250e, and partially etched segments 250b and 250c of semiconductor package 231 are not covered by molding compound 292b. Thus, semiconductor package 231 can be attached to other semiconductor packages having semiconductor components above and below to form power conversion circuits or cascoded switches, for example.

As illustrated in FIG. 2B, leadframe 252 includes partially etched conductive clip 252a, legless conductive clip 252b and non-etched segment 252c. Partially etched conductive clip 252a, legless conductive clip 252b and non-etched segment 252c have a substantially coplanar top surface. As illustrated in FIG. 2B, partially etched conductive clip 252a has a non-etched portion and a partially etched portion, where the non-etched portion retains a full thickness of leadframe 252 and the partially etched portion has a thickness that is a fraction of the full thickness of leadframe 252.

Partially etched conductive clip 252a is configured to provide clearance for semiconductor die 206, such that power switch 230 on semiconductor die 206 is not electrically shorted to any component to be attached to semiconductor package 231, for example. Legless conductive clip 252b is electrically and mechanically coupled to power electrode 232 of power switch 230. Legless conductive clip 252b is electrically and mechanically coupled to power electrode 232 of power switch 230. Legless conductive clip 252b is physically separated from partially etched conductive clip 252a and non-etched segment 252c, and has a substantially flat body having a substantially uniform thickness, which is the full thickness of leadframe 252.

In the present implementation, partially etched conductive clip 252a, legless conductive clip 252b and non-etched segment 252c are made of the same material, and have a substantially uniform composition. In another implementation, partially etched conductive clip 252a, legless conductive clip 252b and non-etched segment 252c can be made of different materials, and have different compositions. In the present implementation, partially etched conductive clip 252a, legless conductive clip 252b and non-etched segment 252c of leadframe 252 include copper. In another implementation, partially etched conductive clip 252a, legless conductive clip 252b and non-etched segment 252c may include other suitable conductive materials, such as aluminum or tungsten.

As illustrated in FIG. 2B, leadframe 250 includes non-etched segments 250a, 250d and 250e, and partially etched segments 250b and 250c. Non-etched segments 250a, 250d and 250e, and partially etched segments 250b and 250c are different portions of leadframe 250, where non-etched segments 250a, 250d and 250e retain a full thickness of leadframe 250, and partially etched segments 250b and 250c are etched, thus having a fraction of the full thickness of leadframe 250 (e.g., a half or a quarter of the thickness of non-etched segment 250a). Non-etched segments 250a, 250d and 250e, and partially etched segments 250b and 250c are physically separated from one another. In the present implementation, non-etched segments 250a, 250d and 250e, and partially etched segments 250b and 250c are made of the same material, and have a substantially uniform composition. In another implementation, non-etched segments 250a, 250d and 250e, and partially etched segments 250b and 250c can be made of different materials, and have different compositions. In the present implementation, non-etched segments 250a, 250d and 250e, and partially etched segments 250b and 250c of leadframe 250 may include a metal, such as copper, aluminum, or tungsten, a metal alloy, a tri-metal or other conductive material. In the present implementation, partially etched segments 250b and 250c have a substantially uniform thickness that is a fraction of the full thickness of leadframe 250. In another implementation, partially etched segments 250b and 250c can have different thicknesses.

As illustrated in FIG. 2B, since semiconductor die 206 is situated on partially etched segments, as opposed to non-etched segments, of leadframe 250, the overall height of semiconductor die 206 in integrated power semiconductor package 231 can be reduced, such that the leg portion employed in conventional conductive clips can be eliminated. In the present implementation, legless conductive clip 252b has a substantially flat body without a leg portion. In contrast to conventional power semiconductor packages having semiconductor dies attached to non-etched lead segments and conductive clips with leg portions, implementations of the present application utilize partially etched segments 250b and 250c of leadframe 250 to enable semiconductor die 206 to be positioned in semiconductor package 231 with a reduced overall height, which in turn reduces the form factor of semiconductor package 231. In one implementation, semiconductor die 206 may have a thickness of 70 μm (i.e., 70*10⁻⁶ meters) or less, and semiconductor package 231 may have an overall height of 0.4 mm (i.e., 0.4*10⁻³ meters) or less.

In addition, by employing legless conductive clip 252b and semiconductor die 206 configured for attachment to partially etched segments 254b and 254c, the thickness of legless conductive clip 256b can be adjusted to improve high current and voltage handling capability to suit the needs of a particular implementation without significantly affecting the overall height of semiconductor package 231. In addition, because leadframe 252 is exposed on its top surface, and leadframe 250 is exposed on its bottom surface, semiconductor package 231 is highly adaptable, such that it can be directly attached to other semiconductor packages on its top and/or bottom surfaces to form versatile configurations.

Referring now to FIG. 2C, FIG. 2C illustrates a cross-sectional view of an exemplary integrated power assembly of a power switching stage, according to one implementation of the present application. As illustrated in FIG. 2C, integrated power assembly 202 includes semiconductor package 221 stacked directly on top of semiconductor package 231, where semiconductor packages 221 and 231 may correspond to semiconductor packages 221 and 231 in FIGS. 2A and 2B, respectively. In one implementation, semiconductor package 221 may be attached to semiconductor package 231 by utilizing solder, sinter or sinter alloy (not explicitly shown in FIG. 2C), for example.

As illustrated in FIG. 2C, integrated power assembly 202 includes semiconductor die 204 having power switch 220, semiconductor die 206 having power switch 230, leadframe 250 having non-etched segments 250a, 250d and 250e, and partially etched segments 250b and 250c on substrate 290, leadframe 252 having partially etched conductive clip 252a, legless conductive clip 252b and non-etched segment 252c, leadframe 254 having non-etched segments 254a and 254d, and partially etched segments 254b and 254c, and leadframe 256 having partially etched conductive clip 256a and legless conductive clip 256b. In the present implementation, power switches 220 and 230 may correspond to high-side switch 120 and low-side switch 130, respectively, as shown in FIG. 1A, and may be connected as such. Since semiconductor packages 221 and 231 each have exposed top and bottom surfaces, connecting power switches 220 and 230 in a half-bridge can be accomplished by simply stacking semiconductor package 221 on top of semiconductor package 231.

As illustrated in FIG. 2C, semiconductor die 204 includes power switch 220. In an implementation, power switch 220 may correspond to high-side switch 120 in power conversion circuit 100 of FIG. 1A. Control electrode 226 (e.g., gate electrode) and power electrode 224 (e.g., source electrode) of power switch 220 are electrically and mechanically coupled to partially etched segments 254b and 254c, respectively, of leadframe 254. Partially etched segments 254b and 254c of leadframe 254 are directly attached to the exposed top surfaces of partially etched conductive clip 252a and legless conductive clip 252b, respectively, of leadframe 252. Thus, control electrode 226 (e.g., gate electrode) of power switch 220 is electrically coupled to substrate 290 through partially etched segment 254b, partially etched conductive clip 252a and non-etched segment 250a. Power electrode 224 (e.g., source electrode) of power switch 220 is electrically coupled to power electrode 232 (e.g., drain electrode) of power switch 230 through partially etched segment 254c and legless conductive clip 252b, which is in turn electrically coupled to substrate 290 through non-etched segment 250d. Power electrode 222 (e.g., drain electrode) of power switch 220 is electrically coupled to substrate 290 through legless conductive clip 256b, non-etched segment 254d, non-etched segment 252c and non-etched segment 250e.

As illustrated in FIG. 2C, semiconductor die 206 includes power switch 230. In an implementation, power switch 230 may correspond to low-side switch 130 in power conversion circuit 100 of FIG. 1A. Control electrode 236 (e.g., gate electrode) and power electrode 234 (e.g., source electrode) of power switch 230 are electrically and mechanically coupled to partially etched segments 250b and 250c, respectively, of leadframe 250, which are electrically and mechanically coupled to substrate 290. Power electrode 232 (e.g., drain electrode) of power switch 230 is electrically coupled to power electrode 224 (e.g., source electrode) of power switch 220 through partially etched segment 254c and legless conductive clip 252b, which may correspond to switched node 140 in FIG. 1A. Legless conductive clip 252b is in turn electrically coupled to substrate 290 through non-etched segment 250d.

It should be understood that various electrical and/or mechanical connections amongst any of power switch 220, power switch 230, leadframes 250, 252, 254 and 256 can be made by utilizing solder such as lead-free solder, or by utilizing sinter or sinter alloy.

As illustrated in FIG. 2C, in integrated power assembly 202, partially etched conductive clip 256a and legless conductive clip 256b are exposed at the top surface of integrated power assembly 202. As the large top surfaces of partially etched conductive clip 256a and legless conductive clip 256b are exposed (i.e., not covered by molding compound 292a), partially etched conductive clip 256a and legless conductive clip 256b can function as a heatsink to provide enhanced thermal dissipation by radiating heat directly to ambient air, for example. In another implementation, molding compound 292a may cover and fully embed semiconductor die 204 and leadframe 256.

By stacking semiconductor package 221 directly on top of semiconductor package 231, integrated power assembly 202 can advantageously avoid having long routing paths and asymmetric current paths. For example, in the present implementation, the length of the connection between power switch 220 and power switch 230 is primarily determined by the thickness of legless conductive clip 252b. As such, the connection between power switch 220 (e.g., high-side switch) and power switch 230 (e.g., low-side switch) through partially etched segment 254c and legless conductive clip 252b can have low parasitic resistance and inductance.

As illustrated in FIG. 2C, since semiconductor dies 204 and 206 are situated on partially etched segments, as opposed to non-etched segments, of leadframes 254 and 250, respectively, the overall height of each of semiconductor dies 204 and 206 in integrated power assembly 202 can be reduced, such that the leg portion employed in conventional conductive clips can be eliminated. In the present implementation, each of legless conductive clips 252b and 256b has a substantially flat body without a leg portion. As a result, the overall height of integrated power assembly 202 can be reduced, which in turn reduces the form factor of integrated power assembly 202. In contrast to conventional power semiconductor packages having individual semiconductor dies arranged side by side and coupled to a substrate through their respective conductive clips, by stacking semiconductor package 221 having semiconductor die 204 over semiconductor package 231 having semiconductor die 206 on substrate 290, integrated power assembly 202 can advantageously have a reduced footprint, thereby reducing the form factor of integrated power assembly 202. In one implementation, semiconductor dies 204 and 206 may each have a thickness of 70 μm (i.e., 70*10⁻⁶ meters) or less, and integrated power assembly 202 may have an overall height of 0.8 mm (i.e., 0.8*10⁻³ meters) or less.

In an implementation, integrated power assembly 202 having power switches 220 and 230 connected in a half-bridge may correspond to one phase of a three-phase inverter, or more generally a polyphase inverter, which can be used to drive a motor, for example. For example, in integrated power assembly 202, power switch 220 (e.g., a high-side switch) and power switch 230 (e.g., a low-side switch) are connected in a half-bridge, which may be coupled between a high side power bus (e.g., positive input terminal V_{IN(+)} in FIG. 1A) and a low side power bus (e.g., negative input terminal V_{IN(-)} in FIG. 1A) with partially etched segment 254c and legless conductive clip 252b between power switches 220 and 230 as an output terminal (e.g., switched node 140 in FIG. 1A).

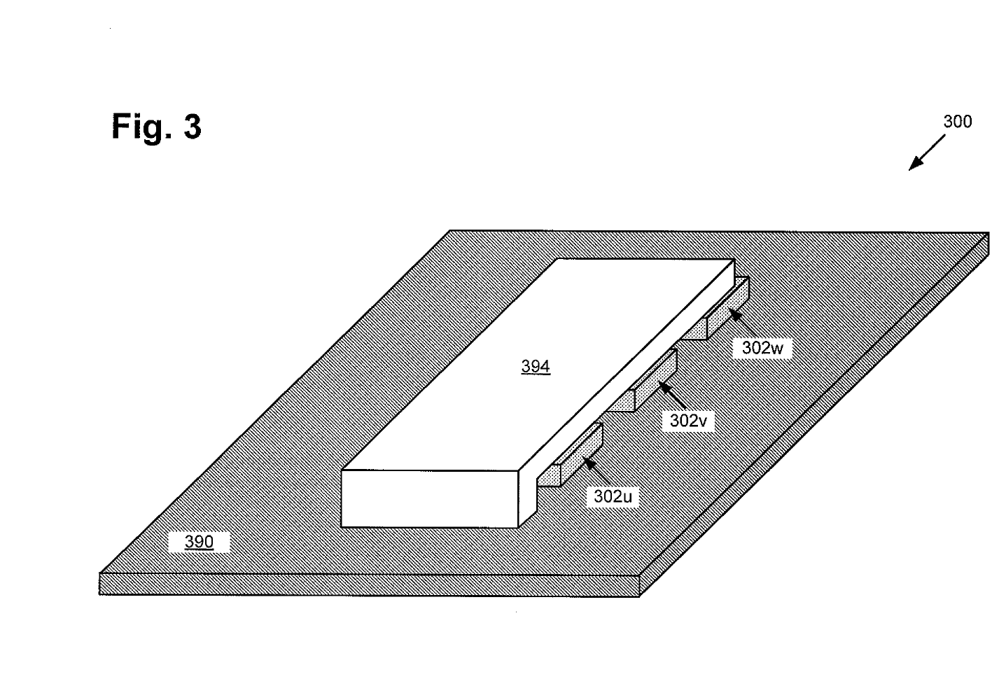

Referring now to FIG. 3, FIG. 3 illustrates a perspective view of a three-phase inverter, in accordance with an implementation of the present application. As illustrated in FIG. 3, three-phase inverter 300 includes integrated power assemblies 302u, 302v and 302w formed on substrate 390 and coupled to power bus 394. In one implementation, integrated power assemblies 302u, 302v and 302w may be a U-phase, a V-phase and a W-phase, respectively, of three-phase inverter 300, which can be used to drive a motor, for example. Each of integrated power assemblies 302u, 302v and 302w in FIG. 3 may correspond to integrated power assembly 202 in FIG. 2C. For example, each of integrated power assemblies 302u, 302v and 302w may include a high-side switch (e.g., power switch 220 in FIG. 2C) and a low-side switch (e.g., power switch 230 in FIG. 2C) connected in a half-bridge in an integrated power assembly (e.g., integrated power assembly 202 in FIG. 2C). Power bus 394 is configured to be affixed to, and provide a high side bus voltage to, the half-bridge (e.g., power electrode 222 of power switch 220 through legless conductive clip 256b in FIG. 2C) in each of integrated power assemblies 302u, 302v and 302w. Moreover, since power bus 394 has a large exposed area on its top surface, power bus 394 can function as a common heatsink for integrated power assemblies 302u, 302v and 302w to provide enhanced thermal dissipation by radiating heat directly to ambient air, for example.

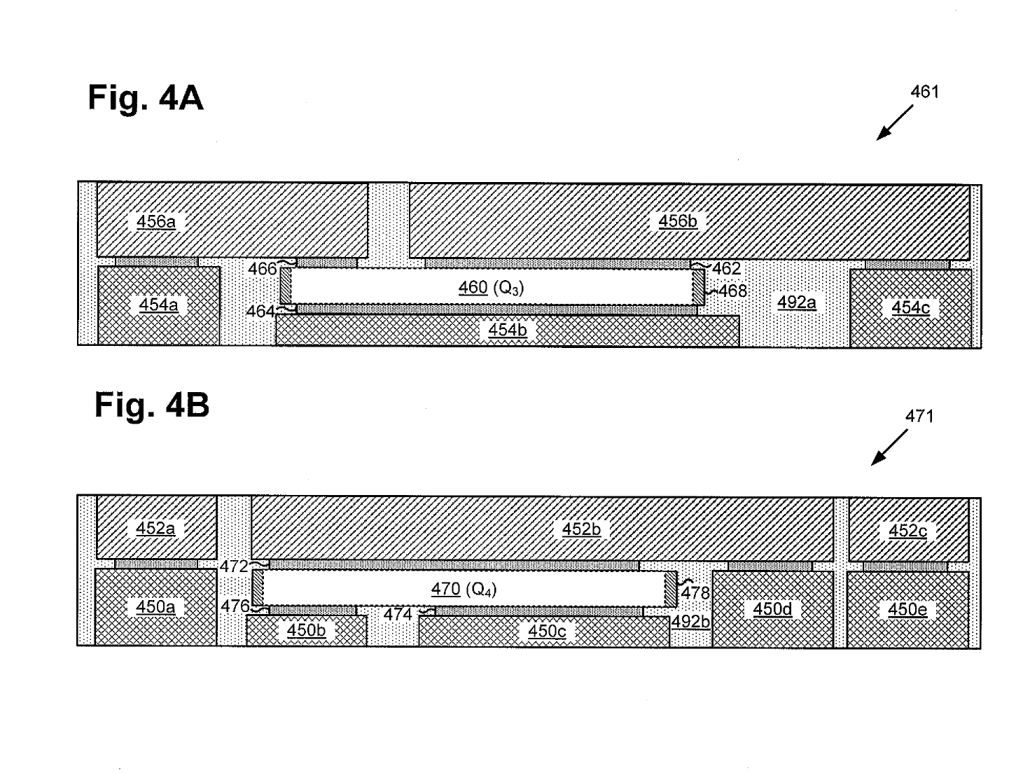

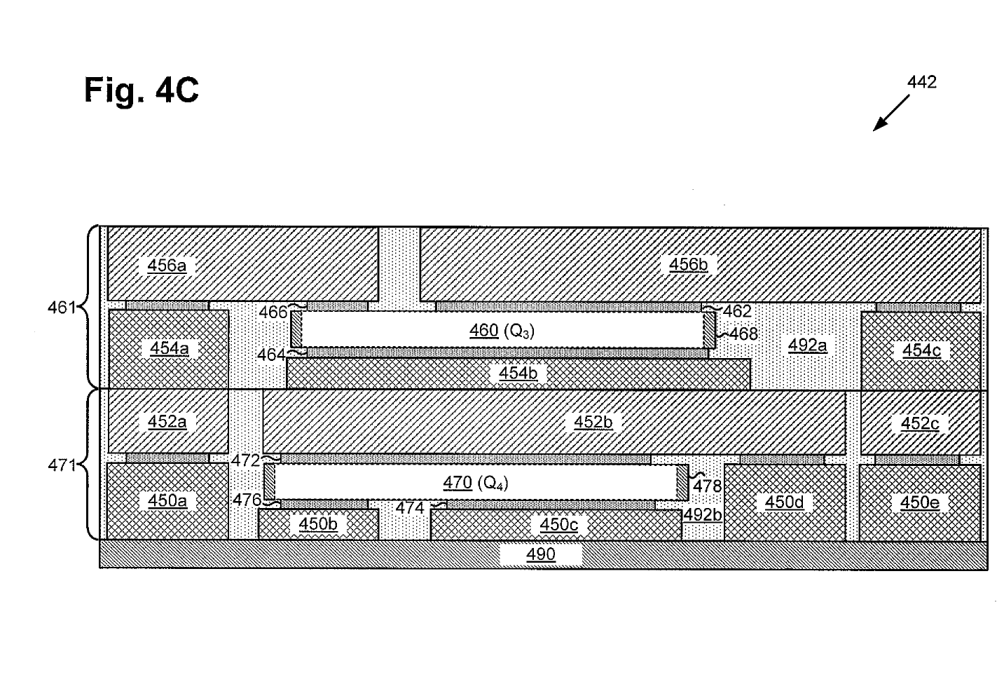

Referring now to FIG. 4A, FIG. 4A illustrates a cross-sectional view of a portion of an exemplary integrated power assembly of a composite switch, according to one implementation of the present application. As illustrated in FIG. 4A, semiconductor package 461 includes semiconductor die 468 having power switch 460, leadframe 454 having non-etched segments 454a and 454c, and partially etched segment 454b, and leadframe 456 having legless conductive clips 456a and 456b. Also, semiconductor package 461 includes molding compound 492a substantially covering leadframe 454, semiconductor die 468 and leadframe 456.

As illustrated in FIG. 4A, semiconductor die 468 includes power switch 460. In one implementation, power switch 460 may correspond to group III-V transistor 160 in enhancement mode composite switch 142 of FIG. 1B. For example, power switch 460 may be a III-Nitride HFET, such as a GaN HEMT. In the present implementation, power switch 460 is a depletion mode transistor, such as a depletion mode GaN transistor. Power switch 460 includes power electrode 462 (e.g., drain electrode) and control electrode 466 (e.g., gate electrode) situated on a top surface of semiconductor die 468, and power electrode 464 (e.g., source electrode) situated on a bottom surface of semiconductor die 468. Power electrodes 462 and 464 and control electrode 466 of power switch 460 may each include a solderable front metal, such as titanium, copper, nickel or silver.

As illustrated in FIG. 4A, control electrode 466 (e.g., gate electrode) of power switch 460 is electrically and mechanically coupled to legless conductive clip 456a of leadframe 456. Power electrode 462 (e.g., drain electrode) of power switch 460 is electrically and mechanically coupled to legless conductive clip 456b of leadframe 456. Power electrode 464 (e.g., source electrode) of power switch 460 is electrically and mechanically coupled to partially etched segment 454b of leadframe 454.

As illustrated in FIG. 4A, leadframe 454 includes non-etched segments 454a and 454c, and partially etched segment 454b. Control electrode 466 situated on the top surface of semiconductor die 468 is electrically coupled to non-etched segment 454a through legless conductive clip 456a. Power electrode 462 situated on the top surface of semiconductor die 468 is electrically coupled to non-etched segment 454c through legless conductive clip 456b. Power electrode 464 situated on the bottom surface of semiconductor die 468 is electrically and mechanically coupled to partially etched segment 454b.

As illustrated in FIG. 4A, molding compound 492a substantially covers semiconductor die 468 having power switch 460, leadframe 454 having non-etched segments 454a and 454c and partially etched segment 454b, and leadframe 456 having legless conductive clips 456a and 456b. As illustrated in FIG. 4A, the top surfaces of legless conductive clips 456a and 456b, and the bottom surfaces of non-etched segments 454a and 454c and partially etched segment 454b of semiconductor package 461 are not covered by molding compound 492a. Thus, semiconductor package 461 can be attached to other semiconductor packages having semiconductor components above and below to form power conversion circuits or cascoded switches, for example.

As illustrated in FIG. 4A, leadframe 456 includes legless conductive clips 456a and 456b, where legless conductive clip 456a is physically separated from legless conductive clip 456b. Legless conductive clips 456a and 456b each have a substantially flat body having a substantially uniform thickness, which is the full thickness of leadframe 456. In the present implementation, legless conductive clips 456a and 456b are made of the same material, and have a substantially uniform composition. In another implementation, legless conductive clips 456a and 456b can be made of different materials, and have different compositions. In the present implementation, legless conductive clips 456a and 456b of leadframe 456 include copper. In another implementation, legless conductive clips 456a and 456b may include other suitable conductive materials, such as aluminum or tungsten.

As illustrated in FIG. 4A, leadframe 454 includes non-etched segments 454a and 454c, and partially etched segment 454b. Non-etched segments 454a and 454c, and partially etched segment 454b are different portions of leadframe 454, where non-etched segments 454a and 454c retain a full thickness of leadframe 454, and partially etched segment 254b is etched, thus having a fraction of the full thickness of leadframe 454 (e.g., a half or a quarter of the thickness of non-etched segment 454a). Non-etched segments 454a and 454c, and partially etched segment 454b are physically separated from one another. In the present implementation, non-etched segments 454a and 454c, and partially etched segment 454b are made of the same material, and have a substantially uniform composition. In the present implementation, non-etched segments 454a and 454c, and partially etched segment 454b of leadframe 454 may include a metal, such as copper, aluminum, or tungsten, a metal alloy, a tri-metal or other conductive material. In another implementation, non-etched segments 454a and 454c, and partially etched segment 454b can be made of different materials, and have different compositions. In the present implementation, partially etched segment 454b has a substantially uniform thickness that is a fraction of the full thickness of leadframe 454.

As illustrated in FIG. 4A, since semiconductor die 468 is situated on a partially etched segment, as opposed to a non-etched segment, of leadframe 454, the overall height of semiconductor die 468 in integrated power semiconductor package 461 can be reduced, such that the leg portion employed in conventional conductive clips can be eliminated. In the present implementation, each of legless conductive clips 456a and 456b has a substantially flat body without a leg portion. In contrast to conventional power semiconductor packages having semiconductor dies attached to non-etched lead segments and conductive clips with leg portions, implementations of the present application utilize partially etched segment 454b of leadframe 454 to enable semiconductor die 468 to be positioned in semiconductor package 461 with a reduced overall height, which in turn reduces the form factor of semiconductor package 461. In one implementation, semiconductor die 468 may have a thickness of 70 μm (i.e., 70*10⁻⁶ meters) or less, and semiconductor package 461 may have an overall height of 0.4 mm (i.e., 0.4*10⁻³ meters) or less.

In addition, by employing legless conductive clip 456b and semiconductor die 468 configured for attachment to partially etched segment 454b, the thickness of legless conductive clip 456b can be adjusted to improve high current and voltage handling capability to suit the needs of a particular implementation without significantly affecting the overall height of semiconductor package 461. In addition, because leadframe 456 is exposed on its top surface, and leadframe 454 is exposed on its bottom surface, semiconductor package 461 is highly adaptable, such that it can be directly attached to other semiconductor packages on its top and/or bottom surfaces to form versatile configurations.

Referring now to FIG. 4B, FIG. 4B illustrates a cross-sectional view of a portion of an exemplary integrated power assembly of a composite switch, according to one implementation of the present application. As illustrated in FIG. 4B, semiconductor package 471 includes semiconductor die 478 having power switch 470, leadframe 450 having non-etched segments 450a, 450d and 450e, and partially etched segments 450b and 450c, and leadframe 452 having non-etched segments 452a and 452c, and legless conductive clip 452b. Also, semiconductor package 471 includes molding compound 492b substantially covering leadframe 450, semiconductor die 478 and leadframe 452.

As illustrated in FIG. 4B, semiconductor die 478 includes power switch 470. In an implementation, power switch 470 may correspond to group IV transistor 170 in enhancement mode composite switch 142 of FIG. 1B. For example, power switch 470 may be a silicon based power semiconductor device, such as a silicon power MOSFET. In the present implementation, power switch 470 is an enhancement mode transistor, such as an enhancement mode silicon transistor.

As illustrated in FIG. 4B, power switch 470 includes power electrode 472 (e.g., drain electrode) situated on a top surface of semiconductor die 478, and control electrode 476 (e.g., gate electrode) and power electrode 474 (e.g., source electrode) situated on a bottom surface of semiconductor die 478. Power electrodes 472 and 474 and control electrode 476 of power switch 470 may each include a solderable front metal, such as titanium, copper, nickel or silver. Control electrode 476 (e.g., gate electrode) and power electrode 474 (e.g., source electrode) of power switch 470 are electrically and mechanically coupled to partially etched segments 450b and 450c, respectively, of leadframe 450. Power electrode 472 (e.g., drain electrode) is electrically and mechanically coupled to legless conductive clip 452b of leadframe 452, which is electrically and mechanically coupled to non-etched segment 450d of leadframe 450.

As illustrated in FIG. 4B, molding compound 492b substantially covers semiconductor die 478 having power switch 470, leadframe 450 having non-etched segments 450a, 450d and 450e, and partially etched segments 450b and 450c, and leadframe 452 having non-etched segments 452a and 452c, and legless conductive clip 452b. As illustrated in FIG. 4B, the top surfaces of non-etched segments 452a and 452c, and legless conductive clip 452b, and the bottom surfaces of non-etched segments 450a, 450d and 450e, and partially etched segments 450b and 450c of semiconductor package 471 are not covered by molding compound 492b. Thus, semiconductor package 471 can be attached to other semiconductor packages having semiconductor components above and below to form power conversion circuits or cascoded switches, for example.

As illustrated in FIG. 4B, non-etched segments 450a, 450d and 450e, and partially etched segments 450b and 450c are different portions of leadframe 450, where non-etched segments 450a, 450d and 450e retain a full thickness of leadframe 450, and partially etched segments 450b and 450c are etched, thus having a fraction of the full thickness of leadframe 450 (e.g., a half or a quarter of the thickness of non-etched segment 450a). Non-etched segments 450a, 450d and 450c, and partially etched segments 450b and 450c are physically separated from one another. In the present implementation, non-etched segments 450a, 450d and 450e, and partially etched segments 450b and 450c are made of the same material, and have a substantially uniform composition. In the present implementation, non-etched segments 450a, 450d and 450e, and partially etched segments 450b and 450c of leadframe 450 may include a metal, such as copper, aluminum, or tungsten, a metal alloy, a tri-metal or other conductive material. In another implementation, non-etched segments 450a, 450d and 450e, and partially etched segments 450b and 450c can be made of different materials, and have different compositions. In the present implementation, partially etched segments 450b and 450c have a substantially uniform thickness that is a fraction of the full thickness of leadframe 450. In another implementation, partially etched segments 450b and 450c can have different thicknesses.

As illustrated in FIG. 4B, since semiconductor die 478 is situated on partially etched segments, as opposed to non-etched segments, of leadframe 450, the overall height of semiconductor die 478 in integrated power assembly 442 can be reduced, such that the leg portion employed in conventional conductive clips can be eliminated. In the present implementation, legless conductive clip 452b has a substantially flat body without a leg portion. In contrast to conventional power semiconductor packages having semiconductor dies attached to non-etched lead segments and conductive clips with leg portions, implementations of the present application utilize partially etched segments 450b and 450c of leadframe 450 to enable semiconductor die 478 to be positioned in semiconductor package 471 with a reduced overall height, which in turn reduces the form factor of semiconductor package 471. In one implementation, semiconductor die 478 may have a thickness of 70 μm (i.e., 70*10⁻⁶ meters) or less, and semiconductor package 471 may have an overall height of 0.4 mm (i.e., 0.4*10⁻³ meters) or less.

In addition, by employing legless conductive clip 452b and semiconductor die 478 configured for attachment to partially etched segments 450b and 450c, the thickness of legless conductive clip 452b can be adjusted to improve high current and voltage handling capability to suit the needs of a particular implementation without significantly affecting the overall height of semiconductor package 471. In addition, because leadframe 452 is exposed on its top surface, and leadframe 450 is exposed on its bottom surface, semiconductor package 471 is highly adaptable, such that it can be directly attached to other semiconductor packages on its top and/or bottom surfaces to form versatile configurations.

Referring now to FIG. 4C, FIG. 4C illustrates a cross-sectional view of integrated power assembly of a composite switch, according to one implementation of the present application. As illustrated in FIG. 4C, integrated power assembly 442 may include a composite switch, such as enhancement mode composite switch 142 in FIG. 1B, which may correspond to at least one of high-side switch 120 and low-side switch 130 in FIG. 1A. For example, while one integrated power assembly 442 may be utilized as high-side switch 120, another integrated power assembly 442 may be utilized as low-side switch 130 in power conversion circuit 100. In the present implementation, power switches 460 and 470 may correspond to group III-V transistor 160 and group IV transistor 170, respectively, as shown in FIG. 1B, and may be connected as such. In one implementation, semiconductor package 461 may be attached to semiconductor package 471 by utilizing solder, sinter or sinter alloy (not explicitly shown in FIG. 4C), for example.

As illustrated in FIG. 4C, integrated power assembly 442 includes semiconductor package 461 stacked on top of semiconductor package 471, where semiconductor packages 461 and 471 may correspond to semiconductor packages 461 and 471 in FIGS. 4A and 4B, respectively. Integrated power assembly 442 includes semiconductor die 468 having power switch 460, semiconductor die 478 having power switch 470, leadframe 450 having non-etched segments 450a, 450d and 450e, and partially etched segments 450b and 450c on substrate 490, leadframe 452 having non-etched segments 452a and 452c, and legless conductive clip 452b, leadframe 454 having non-etched segments 454a and 454c, and partially etched segment 454b, and leadframe 456 having legless conductive clips 456a and 456b.

As illustrated in FIG. 4C, semiconductor die 468 includes power switch 460. In an implementation, power switch 460 may correspond to group DIV transistor 160 as shown in FIG. 1B. For example, power switch 460 may be a III-Nitride HFET, such as a GaN HEMI. In the present implementation, power switch 460 is a depletion mode transistor, such as a depletion mode GaN transistor. Control electrode 466 (e.g., gate electrode) of power switch 460 is electrically coupled to substrate 490 through legless conductive clip 456a of leadframe 456, non-etched segment 454a of leadframe 454, non-etched segment 452a of leadframe 452 and non-etched segment 450a of leadframe 450. Power electrode 462 (e.g., drain electrode) of power switch 460 is electrically coupled to substrate 490 through legless conductive clip 456b of leadframe 456, non-etched segment 454c of leadframe 454, non-etched segment 452c of leadframe 452 and non-etched segment 450e of leadframe 450. Power electrode 464 (e.g., source electrode) of power switch 460 is electrically and mechanically coupled to partially etched segment 454b of leadframe 454, which is directly attached to the exposed top surface of legless conductive clip 452b of leadframe 452. Thus, power electrode 464 (e.g., source electrode) of power switch 460 is electrically coupled to power electrode 472 (e.g., drain electrode) of power switch 470 through partially etched segment 454b and legless conductive clip 452b, which is in turn electrically coupled to substrate 490 through non-etched segment 450d.

As illustrated in FIG. 4C, semiconductor die 478 includes power switch 470. In an implementation, power switch 470 may correspond to group IV transistor 170 as shown in FIG. 1B. For example, power switch 470 may be a silicon based power semiconductor device, such as a silicon power MOSFET. In the present implementation, power switch 470 is an enhancement mode transistor, such as an enhancement mode silicon transistor.

Power electrode 472 (e.g., drain electrode) of power switch 470 is electrically and mechanically coupled to legless conductive clip 452b of leadframe 452, which is directly attached to partially etched segment 454b of leadframe 454. Thus, power electrode 472 (e.g., drain electrode) of power switch 470 is electrically coupled to power electrode 464 (e.g., source electrode) of power switch 460 through legless conductive clip 452b and partially etched segment 454b. Control electrode 476 (e.g., gate electrode) and power electrode 474 (e.g., source electrode) of power switch 470 are electrically coupled to substrate 490 through partially etched segments 450b and 450c, respectively, of leadframe 450.

It should be understood that various electrical and/or mechanical connections amongst any of power switch 460, power switch 470, leadframes 450, 452, 454 and 456 can be made by utilizing solder such as lead-free solder, or by utilizing sinter or sinter alloy.

As illustrated in FIG. 4C, in integrated power assembly 442, legless conductive clips 456a and 456b of leadframe 456 are exposed at the top surface of integrated power assembly 442. As the large top surfaces of legless conductive clips 456a and 456b are exposed (i.e., not covered by molding compound 492a), legless conductive clips 456a and 456b can function as a heatsink to provide enhanced thermal dissipation by radiating heat directly to ambient air, for example. In another implementation, molding compound 492a may cover and fully embed semiconductor die 468 and leadframe 456.

By stacking semiconductor package 461 directly on top of semiconductor package 471, integrated power assembly 442 can advantageously avoid having long routing paths and asymmetric current paths. For example, in the present implementation, the length of the connection between power switch 460 and power switch 470 is primarily determined by the thickness of legless conductive clip 452b. As such, the connection between power switch 460 and power switch 470 can have low parasitic resistance and inductance.

As illustrated in FIG. 4C, since semiconductor dies 468 and 478 are situated on partially etched segments, as opposed to non-etched segments, of leadframes 454 and 450, respectively, the overall height of each of semiconductor dies 468 and 478 in integrated power assembly 442 can be reduced, such that the leg portion employed in conventional conductive clips can be eliminated. In the present implementation, each of legless conductive clips 452b and 456b has a substantially flat body without a leg portion. As a result, the overall height of integrated power assembly 442 can be reduced, which in turn reduces the form factor of integrated power assembly 442. In contrast to conventional power semiconductor packages having individual semiconductor dies arranged side by side and coupled to a substrate through their respective conductive clips, by stacking semiconductor package 461 having semiconductor die 468 over semiconductor package 471 having semiconductor die 478 on substrate 490, integrated power assembly 442 can advantageously have a reduced footprint, thereby reducing the form factor of integrated power assembly 442. In one implementation, semiconductor dies 468 and 478 may each have a thickness of 70 μm (i.e., 70*10⁻⁶ meters) or less, and integrated power assembly 442 may have an overall height of 0.8 mm (i.e., 0.8*10⁻³ meters) or less.

In an implementation, power switch 460 is cascoded with power switch 470 in integrated power assembly 442 to form an enhancement mode composite switch. Since semiconductor packages 461 and 471 each have exposed top and bottom surfaces, connecting power switches 460 and 470 in a cascoded configuration can be accomplished by stacking semiconductor package 461 on top of semiconductor package 471 as shown in FIG. 4C, and electrically coupling control electrode 466 (e.g., gate electrode) of power switch 460 to power electrode 474 (e.g., source electrode) of power switch 470 through conductive trances (not explicitly shown in FIG. 4C) on substrate 490. Integrated power assembly 442 can provide reduced form factor and enhanced thermal dissipation, while it can also substantially avoid increased parasitic inductance, thermal impedance, and assembly cost.

Thus, implementations of the present application provide advantageous packaging structures and methods for increasing power device selection and variety in packaging the power devices, for example in half-bridge or cascode configurations, while maintaining or improving thermal and electrical performance and form factor. According to the present application, various power transistors utilized in half-bridges or cascode configurations in power converters, such as buck converters and the like, can be selected and packaged together in an efficient and effective manner. In an implementation, one power transistor can be a silicon-only FET while another power transistor can be a GaN FET or a GaN HEMT in a cascode configuration with the silicon-only FET. In another implementation, one transistor can be a silicon-only FET while the other transistor can be another silicon-only FET in a half-bridge configuration. In yet another implementation, one power transistor can be a silicon-only IGBT, while the other power transistor can be a silicon-only FET or a GaN FET or a GaN HEMT. As shown in FIGS. 2A, 2B, 4A and 4B, each individual semiconductor package has exposed top and bottom surfaces to accept electrical and thermal connection with one or more semiconductor packages.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. An integrated power assembly comprising:
a first leadframe having partially etched segments;
a first semiconductor die configured for attachment to a partially etched segment of said first leadframe;
a second leadframe having a legless conductive clip coupled to a top surface of said first semiconductor die;
a third leadframe over said second leadframe and having a partially etched segment;
a second semiconductor die configured for attachment to said partially etched segment of said third leadframe;
wherein said second semiconductor die is coupled to said first semiconductor die through said partially etched segment of said third leadframe.

2. The integrated power assembly of claim 1, wherein said partially etched segment of said third leadframe is situated on said legless conductive clip of said second leadframe.

3. The integrated power assembly of claim 1, wherein said first semiconductor die includes a low-side transistor, and said second semiconductor die includes a high-side transistor coupled to said low-side transistor in a half-bridge.

4. The integrated power assembly of claim 3, wherein at least one of said high-side transistor and said low-side transistor includes silicon.

5. The integrated power assembly of claim 1, wherein said first semiconductor die includes a group IV transistor, and said second semiconductor die includes a group Ill-V transistor in cascade with said group IV transistor.

6. The integrated power assembly of claim 5, wherein said group IV transistor includes silicon.

7. The integrated power assembly of claim 5, wherein said group III-V transistor includes gallium nitride (GaN).

8. The integrated power assembly of claim 1, wherein said first semiconductor die includes a first power switch having a gate electrode and a source electrode on a bottom surface of said first semiconductor die, and a drain electrode on said top surface of said first semiconductor die.

9. The integrated power assembly of claim 1, wherein said second semiconductor die includes a second power switch having a gate electrode and a source electrode on a bottom surface of said second semiconductor die, and a drain electrode on a top surface of said second semiconductor die.

10. The integrated power assembly of claim 1, wherein said second semiconductor die includes a second power switch having a source electrode on a bottom surface of said second semiconductor die, and a gate electrode and a drain electrode on a top surface of said second semiconductor die.

11. An integrated power assembly comprising:
a first semiconductor package having a first power switch configured for attachment to a partially etched segment of a first leadframe, and a second leadframe having a legless conductive clip coupled to a top surface of said first power switch;
a second semiconductor package over said first semiconductor package and having a second power switch configured for attachment to a partially etched segment of a third leadframe;
wherein said second power switch is coupled to said first power switch through said partially etched segment of said third leadframe.

12. The integrated power assembly of claim 11, wherein said partially etched segment of said third leadframe is situated on said legless conductive clip of said second leadframe.

13. The integrated power assembly of claim 11, wherein said first power switch includes a low-side transistor, and said second power switch includes a high-side transistor coupled to said low-side transistor in a half-bridge.

14. The integrated power assembly of claim 13, wherein at least one of said high-side transistor and said low-side transistor includes silicon.

15. The integrated power assembly of claim 11, wherein said first power switch includes a group IV transistor, and said second power switch includes a group III-V transistor in cascode with said group IV transistor.

16. The integrated power assembly of claim 15, wherein said group IV transistor includes silicon.

17. The integrated power assembly of claim 15, wherein said group III-V transistor includes gallium nitride (GaN).

18. The integrated power assembly of claim 11, wherein said first power switch includes a gate electrode and a source electrode on a bottom surface of a first semiconductor die, and a drain electrode on a top surface of said first semiconductor die.

19. The integrated power assembly of claim 11, wherein said second power switch includes a gate electrode and a source electrode on a bottom surface of a second semiconductor die, and a drain electrode on a top surface of said second semiconductor die.

20. The integrated power assembly of claim 11, wherein said second power switch includes a source electrode on a bottom surface of a second semiconductor die, and a gate electrode and a drain electrode on a top surface of said second semiconductor die.
